(19) United States
(12) Patent Application Publication
(10) Pub. No.: US 2013/0168063 A1
(43) Pub. Date: Jul. 4, 2013

(54) ELECTRONIC DEVICE WITH THERMAL STRUCTURE

(71) Applicants: CHIA-HUNG HUNG, Tu-Cheng (TW); TE-YAO YEH, Tu-Cheng (TW); KENG-CHIH LIN, Tu-Cheng (TW); CHIA-HSIEN CHANG, Tu-Cheng (TW)

(72) Inventors: CHIA-HUNG HUNG, Tu-Cheng (TW); TE-YAO YEH, Tu-Cheng (TW); KENG-CHIH LIN, Tu-Cheng (TW); CHIA-HSIEN CHANG, Tu-Cheng (TW)

(73) Assignee: HON HAI PRECISION INDUSTRY CO., LTD., Tu-Cheng (TW)

(21) Appl. No.: 13/611,018

(22) Filed: Sep. 12, 2012

(30) Foreign Application Priority Data
Dec. 30, 2011 (TW) 100150045

(51) Int. Cl. H01L 23/467

(52) U.S. Cl. 165/121

(57) ABSTRACT

An electronic device includes a chassis, a cooler, and a fan assembly. The chassis includes a bottom plate and defines an air inlet and an air outlet. The cooler is secured to the bottom plate. The fan assembly is secured to the bottom plate and defines a case and a roller received in the case. The roller includes a shaft and a number of blades secured to the shaft. An area of the air inlet is greater than an area of the air outlet. The fan assembly is capable of drawing in air into the roller. The air flows into the air inlet along a first direction. The air flows out of the air outlet along a second direction. The first direction is substantially parallel to the second direction. The first direction is substantially perpendicular to the shaft.

### BACKGROUND

1. Technical Field

The present disclosure relates to electronic devices, and particularly to an electronic device with a thermal structure.

2. Description of Related Art

Thermal structures with fan are used in electronic devices, such as notebook computers, for cooling the electronic devices. One way to improve heat dissipation, is to use larger fan blades. However, the trend is for smaller chassis, so some other means must be found to improve heat dissipation.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an electronic device.

FIG. 2 is an exploded, isometric view of a fan assembly of the electronic device of FIG. 1.

FIG. 3 is an assembled view of the fan assembly of FIG. 2.

FIG. 4 is an assembled view of the electronic device of FIG. 1.

FIG. 5 is a cross-sectional view of the electronic device of FIG. 4 taken along a line V-V.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

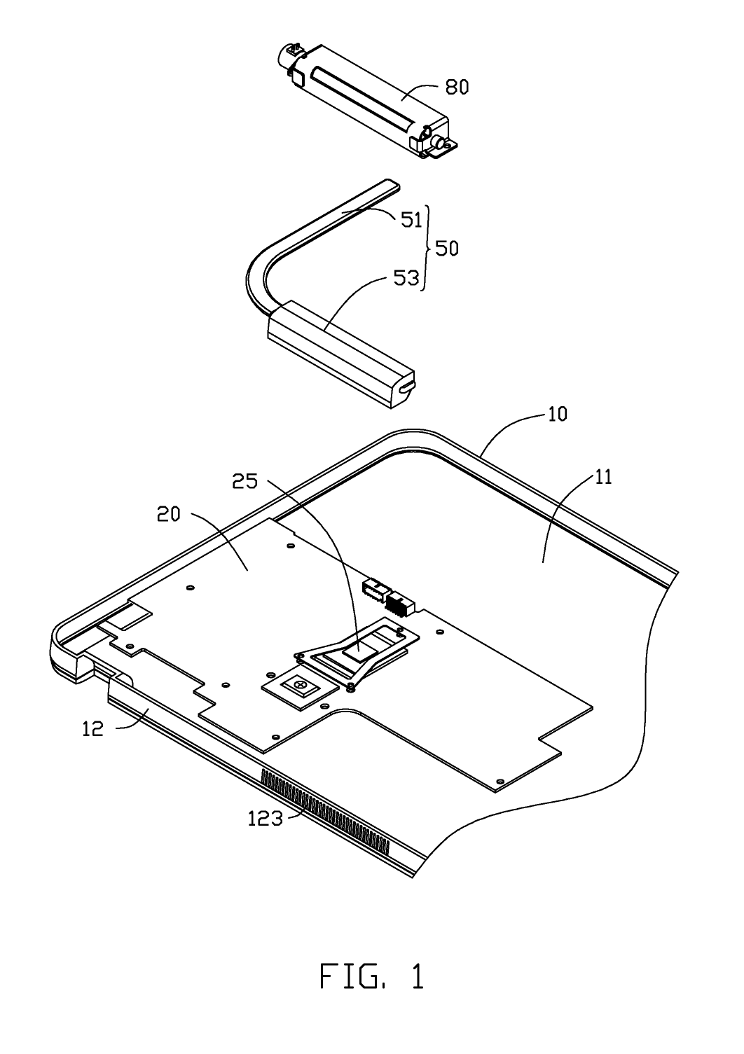

Referring to FIG. 1, an electronic device in accordance with an embodiment is shown. The electronic device comprises a chassis 10, a circuit board 20 secured to the chassis 10, a cooler 50, and a fan assembly 80.

The chassis 10 comprises a bottom plate 11 and a rear plate 12 perpendicularly connected to the bottom plate 11. The rear plate 12 defines a plurality of ventilation holes 123. In one embodiment, the chassis 10 is an enclosure of a notebook computer.

An electronic component 25 is secured to the circuit board 20. The circuit board 20 is secured to the bottom plate 11. In one embodiment, the circuit board 20 is a motherboard.

The cooler 50 comprises a heat pipe 51 and a fin assembly 53 with a plurality of heat dissipating fins mounted therein. A first end of the heat pipe 51 is secured to the fin assembly 53. A second end of the heat pipe 51 touches the electronic component 25. In one embodiment, the heat pipe 51 is “L” shaped.

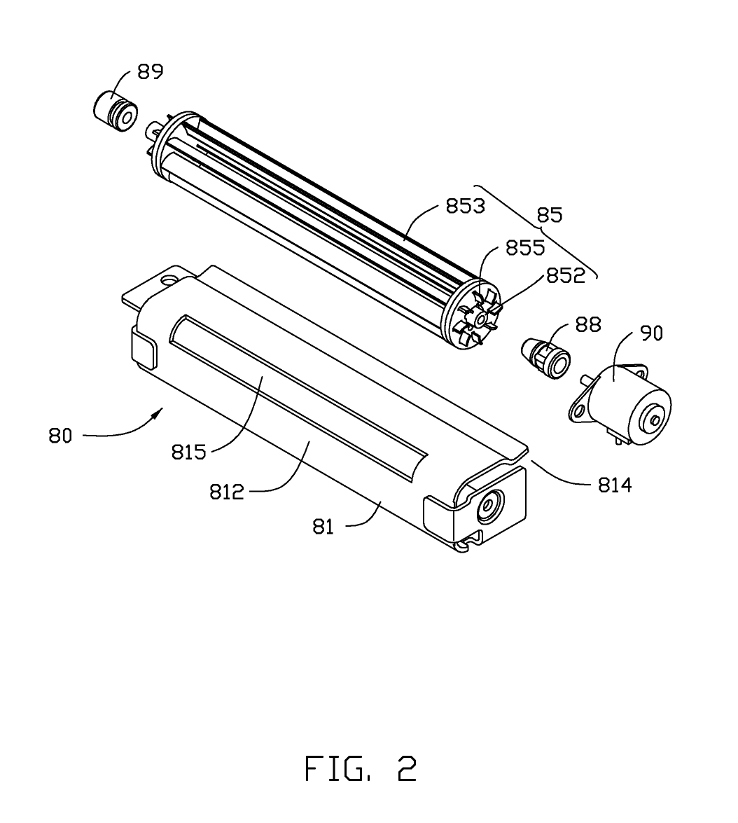

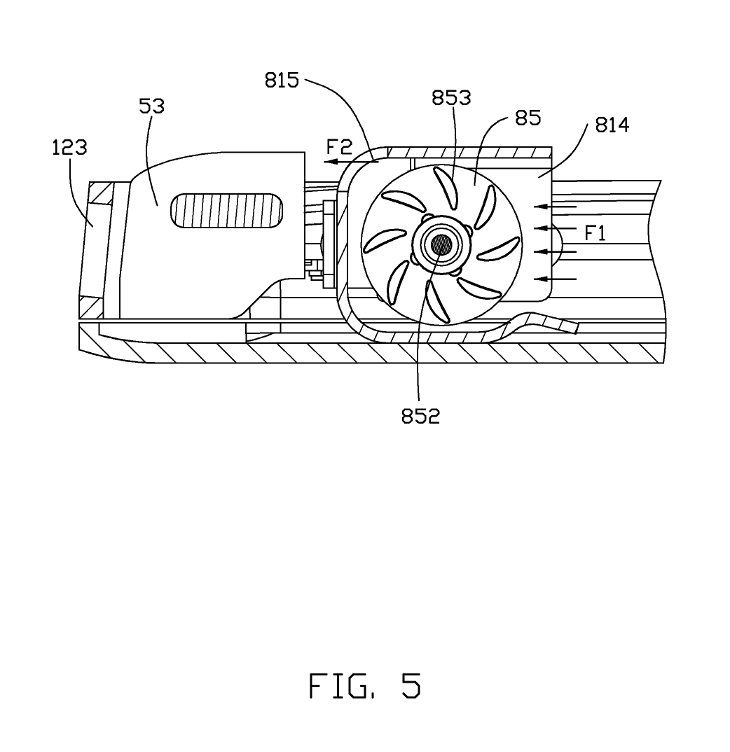

FIG. 2 and FIG. 5 show one embodiment of the fan assembly 80. The fan assembly 80 comprises a case 81, a roller 85, a driving member 88, and a bearing 89. The roller 85 comprises a shaft 852, two trays 855 secured to two opposite ends of the shaft 852, and a plurality of blades 853 secured between the two trays 855. The blades 853 are asymmetrically arranged at a center of the shaft 852. In one embodiment, each blade 853 is curved, a cross section of each blade 853 is curved, and a plane defined by each blade 853 is substantially parallel to the shaft 852. The blades 853 bend in the same direction, such as clockwise or counterclockwise. In other embodiments, the blades 853 are mounted directly to the shaft 852.

The first end and the second end of the shaft 852 are secured to the case 81 by the driving member 88 and the bearing 89. The roller 85 can be rotated by a motor 90. The motor 90 is connected to the circuit board 20 and controls the rotation speed of the roller 85 according to the temperature of the electronic component 25.

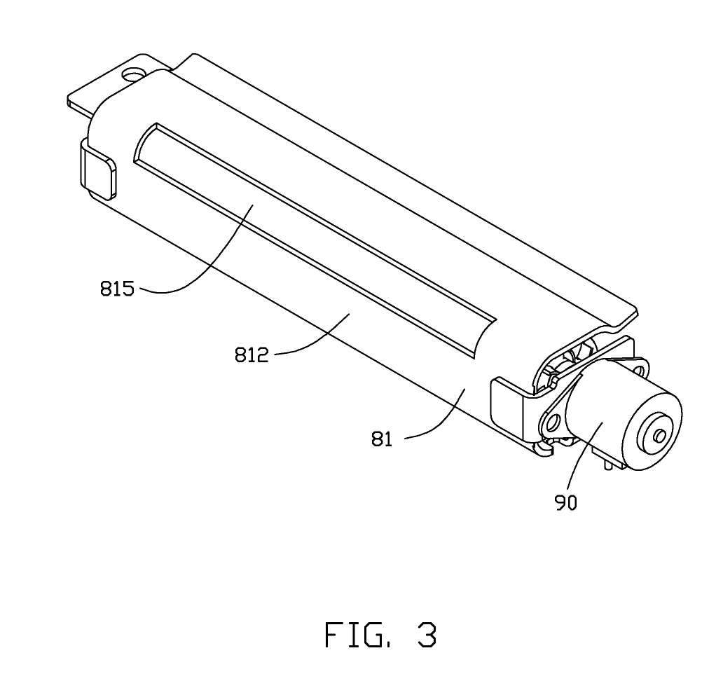

FIGS. 3 and 5 show that the case 81 defines an air inlet 814 and an air outlet 815. The air inlet 814 and the air outlet 815 are located at opposite sides of the case 81. The area of the air inlet 814 is greater than the area of the air outlet 815. Air flows into the air inlet 814 along a first direction F1 and flows out of the air outlet 815 along a second direction F2. The first direction F1 is substantially parallel to the second direction F2. The shaft 852 is substantially perpendicular to the first direction F1 and the second direction F2. The case 81 comprises a side plate 812. The side plate 812 is substantially perpendicular to the second direction F2. The air outlet 815 is located on a top side of the side plate 812. A first height of the air inlet 814, perpendicular to the first direction F1, is equal to or greater than a diameter of the roller 85. The first height of the air inlet 814 is substantially equal to the diameter of the roller 85. A second height of the air outlet 815, perpendicular to the second direction F2, is equal to or smaller than one third of the first height of the air inlet 814.

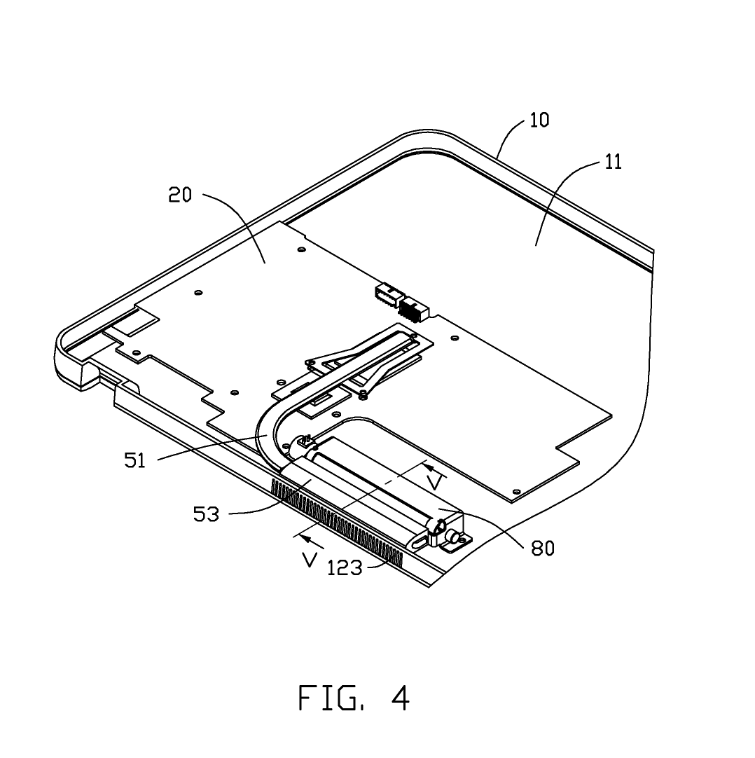

FIG. 4 and FIG. 5 show that, in assembly, the roller 85 is positioned in the case 81. The driving member 88 and the bearing 89 rotatably secure the roller 85 to the case 81. The motor 90 is secured outside the case 81 and connected to the shaft 852. The circuit board 20 is mounted in the chassis 10. The heat pipe 51 is connected to the fin assembly 53 and the electronic component 25. The electronic component 25 is positioned in a side of the ventilation hole 123. The fan assembly 80 is secured to the bottom plate 11 and located in a side of the fin assembly 53. The air outlet 815 faces the fin assembly 53.

In use, the motor 90 rotates the roller 85. The fan assembly 80 draws in air through the air inlet 814. The air flows out of the air outlet 815 to the fin assembly 53 to cool the fin assembly 53. In this embodiment, a cooling efficiency of the fan assembly can be adjusted by changing a ratio between the second height of air outlet 815 and the first height of the air inlet 814.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An electronic device, comprising:
a chassis comprising a bottom plate and defining an air inlet and an air outlet;
a cooler secured to the bottom plate; and
a fan assembly secured to the bottom plate and comprising a case and a roller received in the case, the roller comprising a shaft and a plurality of blades secured to the shaft;
wherein an area of the air inlet is greater than an area of the air outlet; the plurality of blades is capable of drawing in air into the roller; the air flows into the air inlet along a first direction, and the air flows out of the air outlet along a second direction; the first direction is substantially parallel to the second direction; and the first direction is substantially perpendicular to the shaft.

2. The electronic device of claim 1, wherein a cross section of the roller is circular, and a first height of the air inlet along a direction, perpendicular to the first direction, is equal to a diameter of the roller.

3. The electronic device of claim 2, wherein the first height of the air inlet is greater than the diameter of the roller.

4. The electronic device of claim 2, wherein a second height of the air outlet along a direction, perpendicular to the second direction, is equal to or smaller than one third of the first height of the air inlet.

5. The electronic device of claim 1, wherein the plurality of blades is arranged symmetrically at a center of the shaft.

6. The electronic device of claim 5, wherein a cross section of each of the plurality of blades is curved.

7. The electronic device of claim 6, wherein the plurality of blades are bent towards a same direction.

8. The electronic device of claim 5, wherein the roller further comprises two trays secured to two opposite ends of the shaft, and each of the plurality of blades is secured to the two trays.

9. The electronic device of claim 1, wherein the chassis further comprises a side plate substantially perpendicular to the second direction, and the air outlet is located on a side of the side plate.

10. The electronic device of claim 1, wherein the cooler comprises a heat pipe and a fin assembly secured to the heat pipe, and the heat pipe is “L” shaped.

11. An electronic device, comprising:
a chassis comprising a bottom plate and defining an air inlet and an air outlet;
a cooler secured to the bottom plate; and
a fan assembly secured to the bottom plate and comprising a case and a roller received in the case, the roller comprising a shaft and a plurality of blades secured to the shaft;
wherein the plurality of blades is capable of drawing in air into the roller; the air flows into the air inlet along a first direction, and the air flows out of the air outlet along a second direction; the first direction is substantially parallel to the second direction; the first direction is substantially perpendicular to the shaft; and a first height of the air inlet, along a direction perpendicular to the first direction, is greater than a second height of the air outlet, along a direction perpendicular to the second direction.

12. The electronic device of claim 11, wherein a cross section of the roller is circular, and the first height of the air inlet, perpendicular to the first direction, is equal to a diameter of the roller.

13. The electronic device of claim 12, wherein the first height of the air inlet is greater than the diameter of the roller.

14. The electronic device of claim 12, wherein the second height of the air outlet is equal to or smaller than one third of the first height of the air inlet.

15. The electronic device of claim 11, wherein the plurality of blades is arranged symmetrically at a center of the shaft.

16. The electronic device of claim 15, wherein a cross section of each of the plurality of blades is curved.

17. The electronic device of claim 16, wherein each of the plurality of blades is bent towards a same direction.

18. The electronic device of claim 15, wherein the roller further comprises two trays secured to two opposite ends of the shaft, and each of the plurality of the blades is secured to the two trays.

19. The electronic device of claim 11, wherein the chassis further comprises a side plate substantially perpendicular to the second direction, and the air outlet is located on a side of the side plate.

20. The electronic device of claim 11, wherein the cooler comprises a heat pipe and a fin assembly secured to the heat pipe, and the heat pipe is “L” shaped.
